(19) United States
(12) Patent Application Publication
(10) Pub. No.: US 2009/0250768 A1
(43) Pub. Date: Oct. 8, 2009

(54) SEMICONDUCTOR MEMORY DEVICE AND METHOD OF MANUFACTURING THE SAME

(75) Inventors: Atsuhiro SATO, Yokohama-shi (JP); Fumitaka ARAI, Yokohama-shi (JP); Yoshio OZAWA, Yokohama-shi (JP); Takeshi KAMIGAICHI, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/408,119

(22) Filed: Mar. 20, 2009

(30) Foreign Application Priority Data
Apr. 2, 2008 (JP) 2008-096243

(51) Int. Cl. H01L 27/088; H01L 21/28

(52) U.S. Cl. 257/392; 438/585; 438/769; 257/E27.061; 257/E21.19

(57) ABSTRACT

A semiconductor memory device according to the present invention includes: a first transistor formed on a semiconductor substrate 11, the first transistor including a first gate-insulating film 14a that is oxynitrided; and a second transistor including a second gate-insulating film 14b formed on the semiconductor substrate 11 and a barrier film 20 formed at least partially on the second gate-insulating film 14b, the second gate-insulating film having a lower nitrogen atom concentration than the first gate-insulating film.

### CROSS-REFERENCE TO RELATED APPLICATION

This application is based on and claims the benefit of priority from the prior Japanese Patent Application No. 2008-96243, filed on Apr. 2, 2008, the entire contents of which are incorporated herein by reference.

### BACKGROUND OF THE INVENTION

1. Field of the Invention

The present invention relates to a semiconductor memory device, and more particularly, to a non-volatile memory that has an improved breakdown voltage and a method of manufacturing the same.

2. Description of the Related Art

The electrically erasable and programmable read only memory (EEPROM) is well-known as a non-volatile semiconductor memory that can electrically write and erase data. One of the EEPROMs is a flash EEPROM, which can electrically erase all data.

A NAND flash memory is well-known as an exemplary flash EEPROM. NAND flash memories can be readily and highly integrated and thus have widely been used.

In conventional semiconductor devices, one method to reduce the leak current is oxynitridation of the gate-insulating film (see, for example, JP 2006-114816). Attempts have been made to apply the method to NAND flash memory to oxynitride the gate-insulating film in the cell area in order to improve the reliability of the gate-insulating film.

The method has a problem, however, that the gate-insulating film in the transistor region is also oxynitrided and thus the positive fixed electric charge in the gate-insulating film may reduce the threshold voltage. To avoid this, the impurity diffusion concentration in the channel region may be increased. This method has, however, a different problem that the breakdown voltage (such as a surface breakdown voltage) decreases.

### SUMMARY OF THE INVENTION

One aspect of the present invention is a semiconductor memory device including: a first transistor formed on a semiconductor substrate, said first transistor including a first gate-insulating film that is oxynitrided; and a second transistor including a second gate-insulating film formed on the semiconductor substrate and a barrier film formed at least partially on the second gate-insulating film, the second gate-insulating film having a lower nitrogen atom concentration than the first gate-insulating film.

Another aspect of the present invention is a method of manufacturing a semiconductor memory device, including the steps of: forming a first gate-insulating film on a semiconductor substrate in a region where a first transistor is to be formed, and forming a second gate-insulating film that is thicker than the first gate-insulating film on the semiconductor substrate in a region where a second transistor is to be formed; forming a barrier film on the second gate-insulating film; and oxynitriding the first gate-insulating film using the barrier film as a mask.

Still another aspect of the present invention is a method of manufacturing a semiconductor memory device, including the steps of: forming an insulating film on a semiconductor substrate; forming a barrier film on the insulating film; removing the insulating film and the barrier film in a first region where a first transistor is to be formed, thus exposing the semiconductor substrate; forming a first gate-insulating film in the first region where the insulating film and barrier film are removed; and oxynitriding the first gate-insulating film using the barrier film as a mask.

### BRIEF DESCRIPTION OF THE DRAWINGS

FIG. 1 is a schematic cross-sectional view of a non-volatile memory according to a first embodiment of the present invention;

FIG. 2 illustrates a method of manufacturing the non-volatile memory according to the first embodiment;

FIG. 3 illustrates a method of manufacturing the non-volatile memory according to the first embodiment;

FIG. 4 illustrates a method of manufacturing the non-volatile memory according to the first embodiment;

FIG. 5 illustrates a method of manufacturing the non-volatile memory according to the first embodiment;

FIG. 6 illustrates a method of manufacturing the non-volatile memory according to the first embodiment;

FIG. 7 illustrates a method of manufacturing the non-volatile memory according to the first embodiment. FIG. 8 illustrates a method of manufacturing a NAND flash memory according to the first embodiment;

FIG. 9 illustrates a method of manufacturing the non-volatile memory according to the first embodiment;

FIG. 10 illustrates a method of manufacturing the non-volatile memory according to the first embodiment;

FIG. 11 illustrates a method of manufacturing the non-volatile memory according to the first embodiment;

FIG. 12 illustrates a method of manufacturing the non-volatile memory according to the first embodiment;

FIG. 13 illustrates a method of manufacturing the non-volatile memory according to the first embodiment;

FIG. 14 illustrates a method of manufacturing the non-volatile memory according to the first embodiment;

FIG. 15 illustrates a method of manufacturing the non-volatile memory according to the first embodiment;

FIG. 16 illustrates a method of manufacturing the non-volatile memory according to the first embodiment;

FIG. 17 illustrates a method of manufacturing the non-volatile memory according to the first embodiment;

FIG. 18 illustrates a method of manufacturing the non-volatile memory according to the first embodiment;

FIG. 19 is a schematic cross-sectional view of a non-volatile memory according to a second embodiment of the present invention; and

FIG. 20 is a schematic cross-sectional view of a non-volatile memory according to a third embodiment of the present invention.

### DETAILED DESCRIPTION OF THE EMBODIMENTS

### Embodiments of Semiconductor Memory Device

### First Embodiment

With reference to the accompanying drawings, a semiconductor memory device according to a first embodiment of the present invention will be described in more detail below.

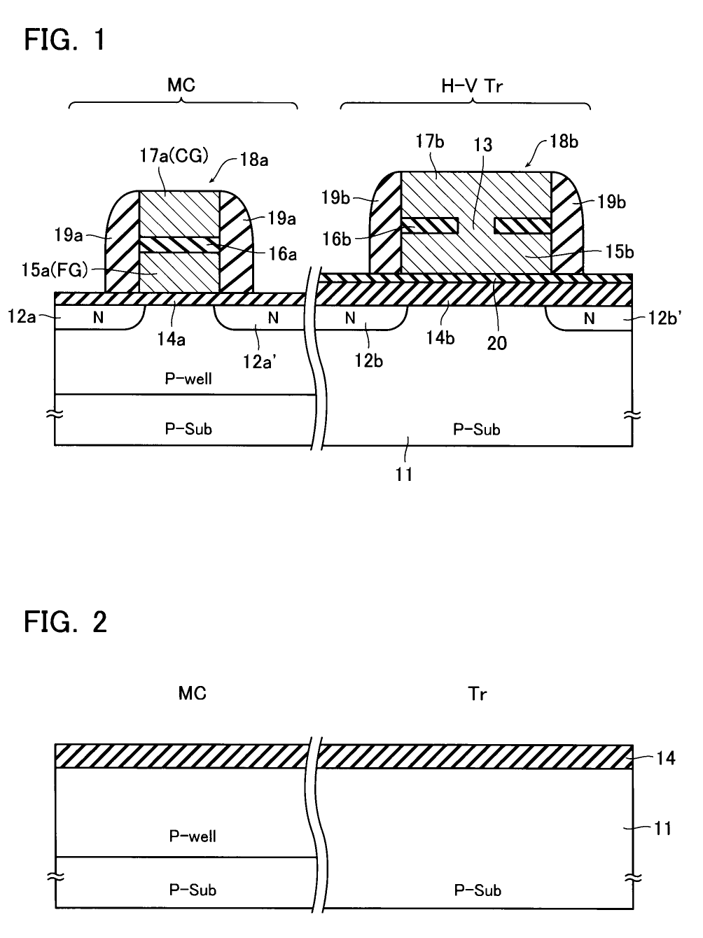

FIG. 1 is a schematic cross-sectional view of a cell area and a peripheral transistor region in a non-volatile memory according to the first embodiment of the present invention. For simplicity and clarity of illustration, elements in the drawings have not necessarily been drawn to scale.

The non-volatile memory in the first embodiment includes a memory cell transistor (MC) that corresponds to a first transistor and a high voltage operation peripheral transistor (HV-Tr) that corresponds to a second transistor. The high voltage operation peripheral transistor (HV-Tr) controls the memory cell transistor (MC). An insulating layer to isolate the gate electrodes is omitted here.

First, the configuration of the memory cell transistor (MC) will be described below. The memory cell transistor (MC) includes a p type silicon substrate 11, a gate-insulating film 14a on the silicon substrate 11, the film 14a including, for example, a silicon oxide film, and a gate electrode 18a on the gate-insulating film 14a. The gate electrode 18a includes a floating gate 15a, the floating gate 15a including, for example, electrically conductive polysilicon doped with impurities such as phosphorus (P), an inter-gate dielectric film 16a deposited on the floating gate 15a, and a control gate 17a deposited on the inter-gate dielectric film 16a. The gate-insulating film 14a is oxynitrided, as described below. The film 14a includes, for example, an oxynitride film SiOₓN_{y} having a thickness of about 8 nm. The oxynitride film has an effect of decreasing traps of electrons moving between the floating gate 15a and the semiconductor substrate 11 during data write/erase.

The inter-gate dielectric film 16a deposited on top of the floating gate 15a may have a high dielectric constant and include, for example, an ONO film (SiO₂/SiN/SiO₂) having a thickness of about 7 nm to about 20 nm. The control gate 17a deposited on top of the inter-gate dielectric film 16a may include, for example, electrically conductive polysilicon.

The sides of the gate electrode 18a each have a sidewall 19a formed thereon. The sidewall 19a includes, for example, a silicon nitride film.

The surface of the p type silicon substrate 11 has n type impurity diffusion regions 12a and 12a′ formed therein. The impurity diffusion regions 12a and 12a′ are formed in self-alignment with the gate electrode 18a and sandwich the electrode 18a. The regions 12a and 12a′ are doped with impurities for the source or drain such as phosphorus (P) and the like.

The p type silicon substrate 11 in the memory cell area may be a p type well that has a higher impurity concentration than the p type silicon substrate 11. The memory cell transistor (MC) may thus have a higher threshold. The cut-off characteristics may thus be improved even if the transistor has a shorter gate length when it is reduced in size. A channel region is formed in the surface of the semiconductor substrate 11 that is sandwiched between the n type impurity diffusion regions 12a and 12a′. The channel region may adjust the threshold voltage of the memory cell transistor (MC).

The memory cell transistor (MC) may be referred to as a type of MOS transistor because a voltage is applied to the gate electrode 18a to form a channel in a surface of the semiconductor substrate 11 under the floating gate 15a.

Next, the configuration of the high voltage operation peripheral transistor (HV-Tr) will be described below. The high voltage operation peripheral transistor (HV-Tr) includes, for example, a transistor that operates at a voltage of about 30 V. The high voltage operation peripheral transistor (HV-Tr) includes the p type silicon substrate 11, a gate-insulating film 14b formed on the p type silicon substrate 11, the film 14b including, for example, a silicon oxide film, a barrier film 20 on the gate-insulating film 14b as described below, and a gate electrode 18b on the barrier film 20. The gate electrode 18b includes a lower gate 15b, the lower gate 15b including electrically conductive polysilicon doped with impurities such as phosphorus (P) or the like, an inter-gate dielectric film 16b deposited on the lower gate 15b, and an upper gate 17b deposited on the lower gate 15b via the inter-gate dielectric film 16b. The gate-insulating film 14b has a thickness of, for example, about 20 nm to 50 nm to provide a high breakdown voltage of, for example, about 5 V to 30 V. In the first embodiment, the barrier film 20 deposited on the gate-insulating film 14b has a thickness of about 5 nm and includes, for example, silicon nitride film (SiN). According to the first embodiment, the barrier film 20 reduces the oxynitridation of the gate-insulating film 14b. Specifically, the gate-insulating film 14b has a lower nitrogen atom concentration than the gate-insulating film 14a. The inter-gate dielectric film 16b deposited on top of the lower gate 15b may have a high dielectric constant and include, for example, an ONO film (SiO₂/SiN/SiO₂) having a thickness of about 7 nm to about 20 nm. The inter-gate dielectric film 16b has an opening 13 formed at its generally center portion on the top surface of the lower gate 15b. The upper gate 17b deposited on top of the inter-gate dielectric film 16b may include, for example, electrically conductive polysilicon.

The upper gate 17b is in electrical connection with the lower gate 15b via the opening 13. This structure allows the gate electrode 18b of the high voltage operation peripheral transistor (HV-Tr) to have a one-layer structure.

The sides of the gate electrode 18b each have a sidewall 19b formed thereon. The sidewall 19b includes, for example, a silicon nitride film or a silicon oxide film.

The surface of the p type silicon substrate 11 has n type impurity diffusion regions 12a and 12a′ formed therein. The impurity diffusion regions 12a and 12a′ are formed in self-alignment with the gate electrode 18b and sandwich the electrode 18b. The regions 12a and 12a′ are doped with impurities for the source or drain such as phosphorus (P) and the like.

The p type silicon substrate 11 in the high voltage operation peripheral transistor region may be a p type well. A channel region is formed in the surface of the semiconductor substrate 11 that is sandwiched between the n type impurity diffusion regions 12b and 12b′. The channel region may adjust the threshold voltage of the high voltage operation peripheral transistor (HV-Tr).

### Embodiments of Manufacturing Method

With reference to the accompanying drawings, an embodiment of a method of manufacturing the NAND flash memory will be described below. FIGS. 2 to 18 illustrate the steps of manufacturing the NAND flash memory in this embodiment.

As shown in FIG. 2, the photolithography technology is used to form a mask (not shown) covering the peripheral transistor region. Ion implantation is then applied to the memory cell area to implant, for example, B to form a p well. The mask is then removed. The surface of the semiconductor substrate 11 such as a silicon substrate is then thermally oxidized to form the gate-insulating film 14 having a thickness of, for example, 40 nm. The film 14 includes, for example, a silicon oxide film.

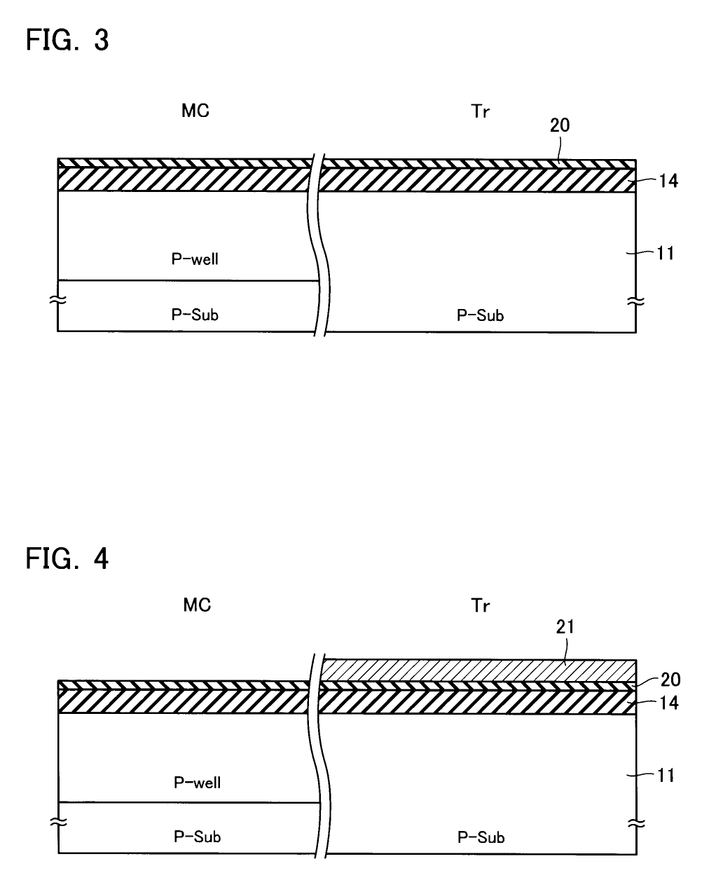

As shown in FIG. 3, the barrier film 20 such as a silicon nitride film having a thickness of, for example, 5 nm is deposited on the gate-insulating film 14 using, for example, the low-pressure CVD. The barrier film 20 may be any film other than the silicon nitride film that may function as a mask after the oxynitridation process as described below. The barrier film 20 may be, for example, a silicon fluoride (SiF₄) film.

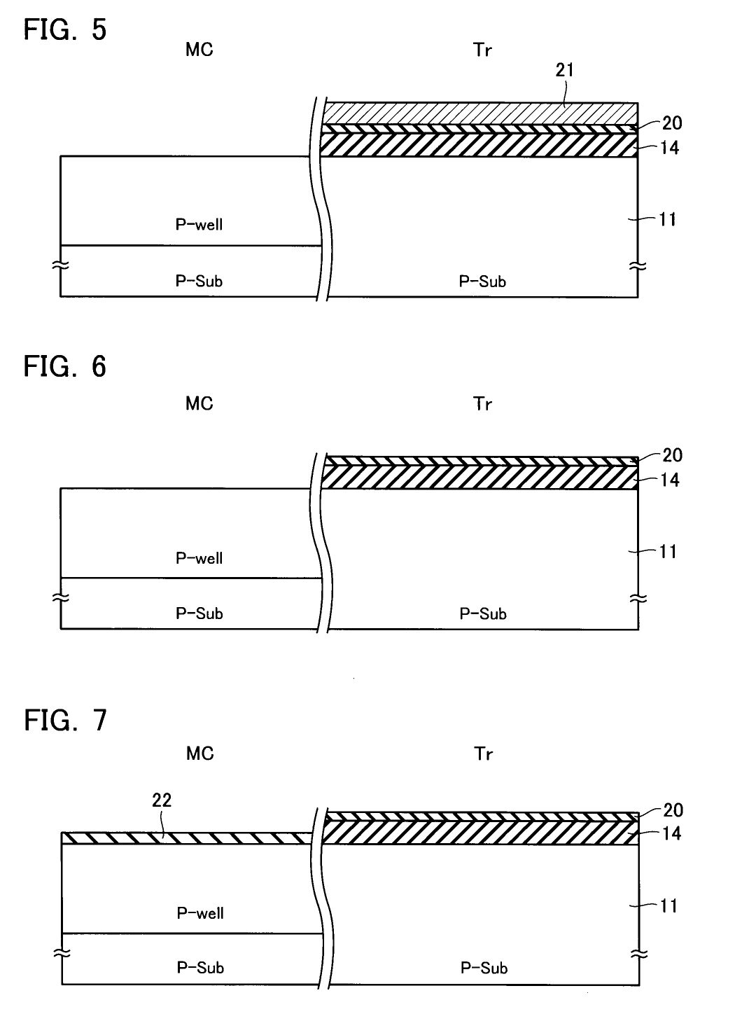

As shown in FIG. 4, a resist is applied over the entire surface. The photolithography technology is used to form a resist mask 21 covering the peripheral transistor region.

As shown in FIG. 5, the barrier film 20 in the peripheral memory cell area is removed using hot phosphoric acid or chemical dry etching (CDE). The silicon oxide film 14 is then wet etched using dilute hydrofluoric acid (DHF) and the like. A surface of the semiconductor substrate that resides in the memory cell area is thus exposed.

As shown in FIG. 6, the resist mask 21 in the peripheral transistor region is peeled off using O₂ ashing and the like.

As shown in FIG. 7, thermal oxidation is performed to form a base oxide layer 22 such as a silicon oxide film having a thickness of, for example, 8 nm on the semiconductor substrate in the memory cell area. During this process, the thickness of the silicon oxide film 14 in the high voltage operation peripheral transistor region does not increase because the film 14 is covered by the barrier film 20.

As shown in FIG. 8, the sample is annealed in an atmosphere of an ammonia (NH₃) gas or an oxidation nitrogen (N₂O) gas at a high temperature of 1100° C. The oxide layer 22 is thus oxynitrided to form the gate-insulating film 14a including an oxynitride film (SiOₓN_{y}). During this process, the oxide layer 14b in the peripheral transistor region is not oxynitrided because the oxide layer 14b is masked by the barrier film 20.

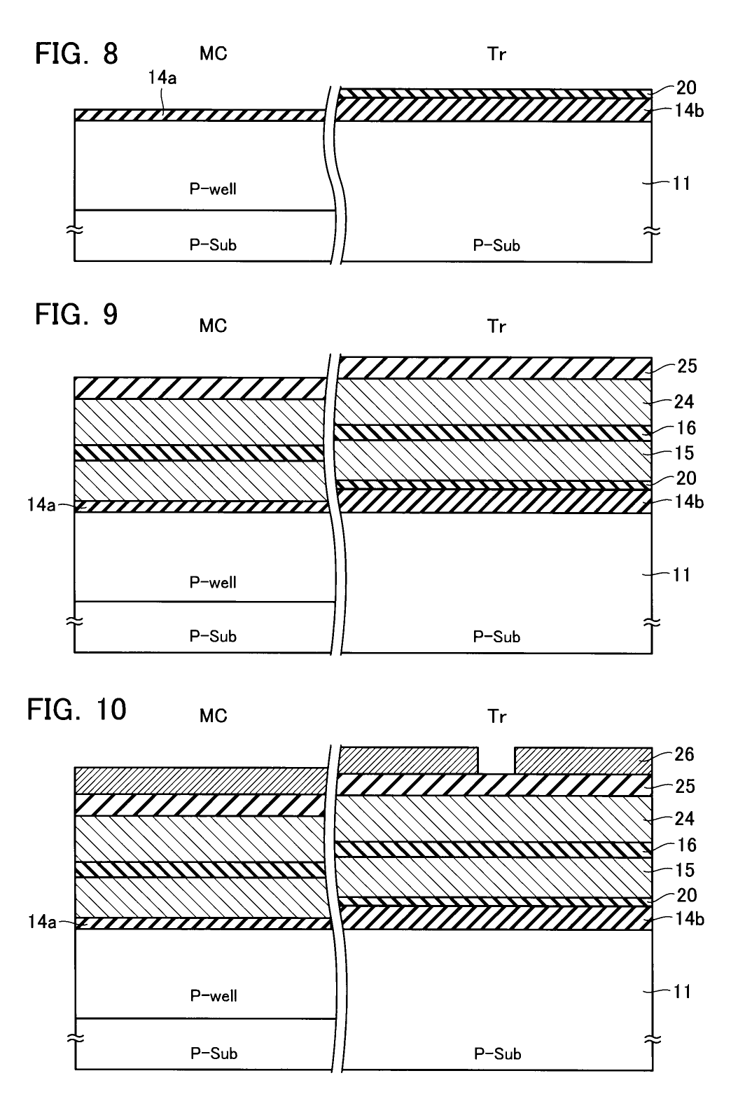

As shown in FIG. 9, the sample is subject to plasma CVD and the like to sequentially deposit the following films: a first polysilicon film 15 having a thickness of 100 nm doped with impurities such as phosphorus (P) at a predetermined concentration, an inter-gate dielectric film 16 such as an ONO (SiO₂—SiN—SiO₂) film, a polysilicon film 24 having a thickness of 50 nm doped with impurities such as phosphorus (P) at a predetermined concentration, and a silicon oxide film 25 such as a TEOS film having a thickness of 150 nm.

As shown in FIG. 10, resist is applied on the silicon oxide film 25, and a mask 26 is then formed using the photolithography technology. The mask 26 has an opening in a region where the opening 13 is to be formed.

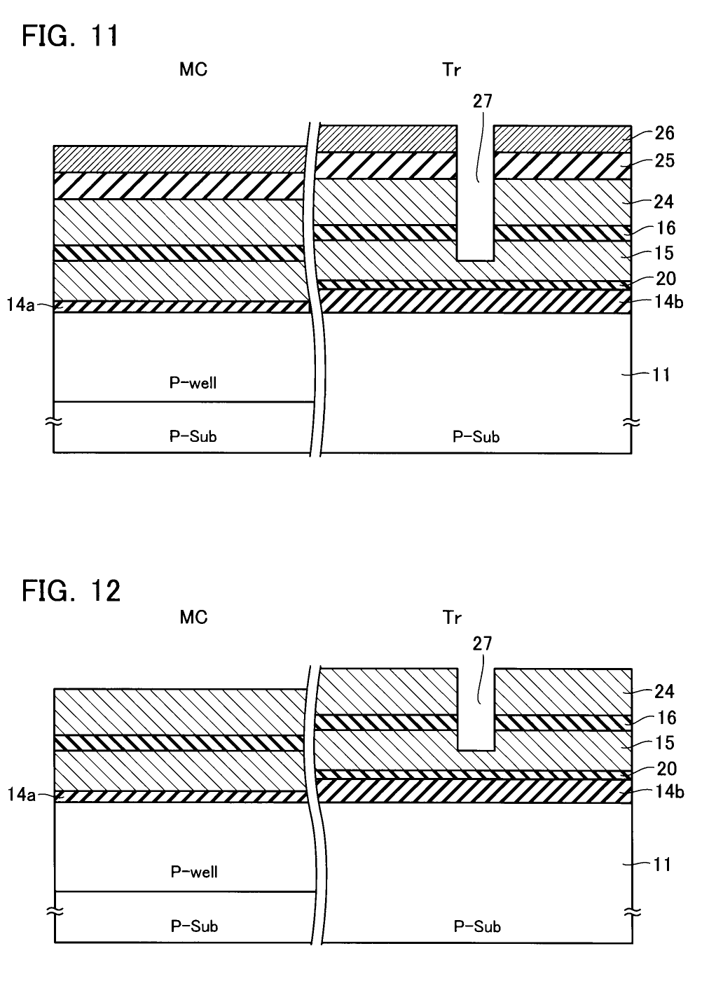

As shown in FIG. 11, the silicon oxide film 25 is selectively removed by dry etching such as RIE using the mask 26. A groove 27 is then selectively formed by etching the sample down to the middle of the first polysilicon film 15. The etching is done by anisotropic etching such as RIE using the silicon oxide film 25 as a hard mask.

As shown in FIG. 12, the mask 26 and the silicon oxide film 25 are removed by, for example, wet etching using dilute hydrofluoric acid (DHF).

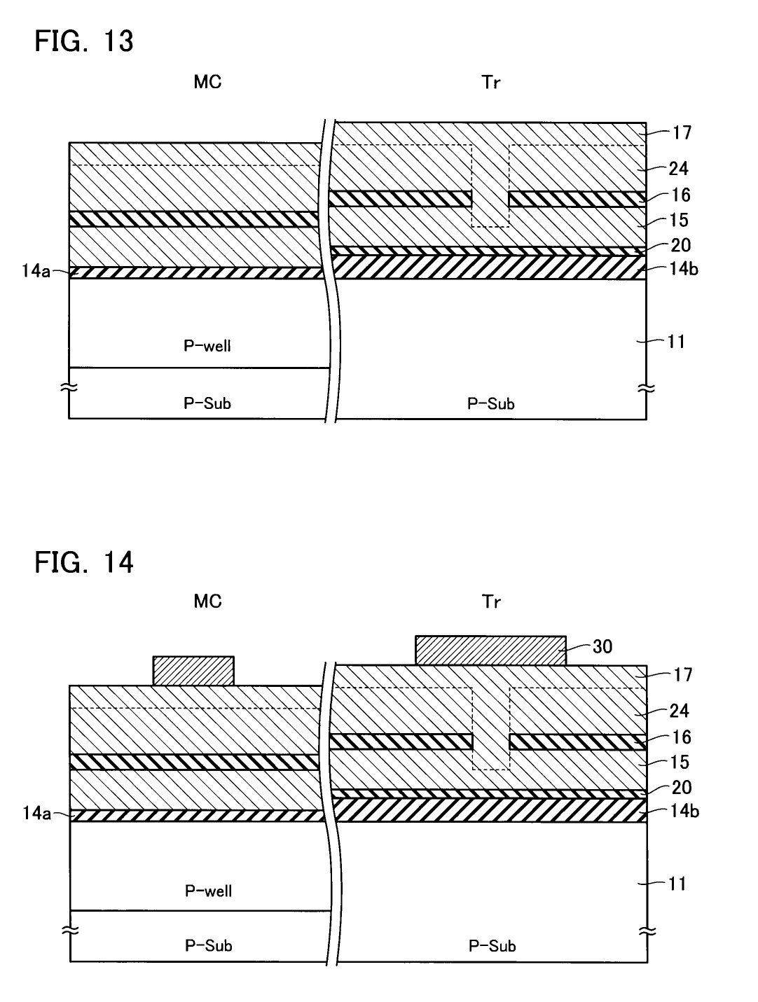

As shown in FIG. 13, a second polysilicon film 17 is deposited to a thickness of, for example, 100 nm by CVD and the like. The second polysilicon film 17 is also embedded into the groove 27.

As shown in FIG. 14, photoresist is applied over the entire surface and patterned to form a mask 30 that covers a region where the gate electrodes 18a and 18b are to be formed.

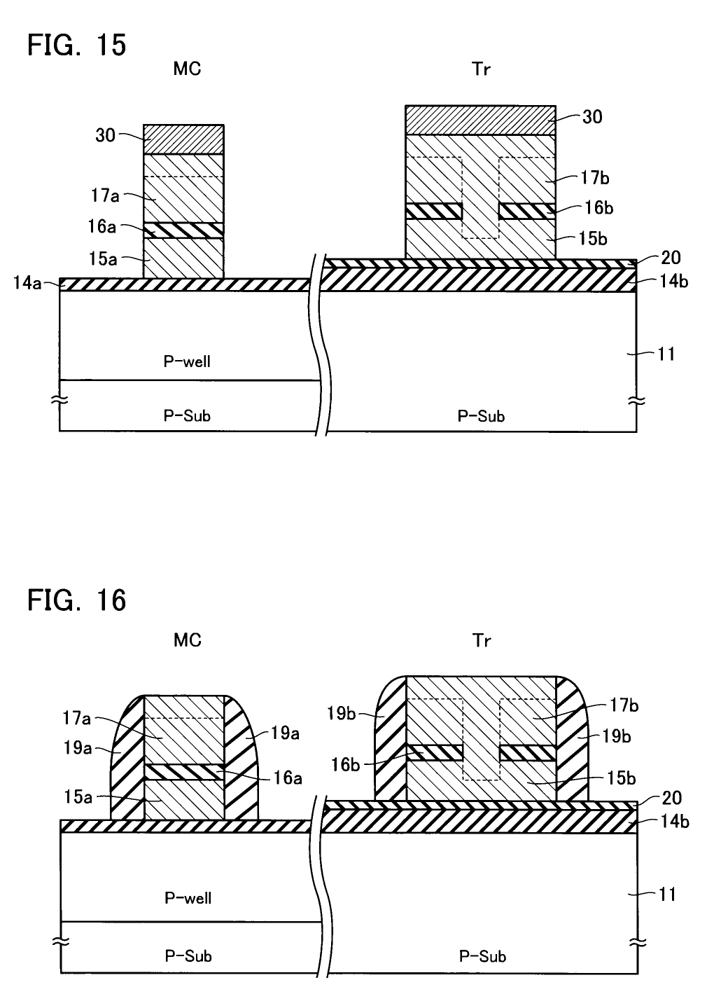

As shown in FIG. 15, anisotropic etching such as RIE is performed using the mask 30 to selectively form the gate electrodes 18a and 18b. During this process, the polysilicon film 24 and the second polysilicon film 17 together form the control gate 17a of the memory cell transistor (MC) and the upper gate 17b of the high voltage operation peripheral transistor (HV-Tr). The mask is then peeled off by O₂ ashing and the like.

As shown in FIG. 16, for example, a silicon nitride film is deposited and then anisotropically etched to form the sidewalls 19a on the sides of the gate electrode 18a and the sidewalls 19b on the sides of the gate electrode 18b.

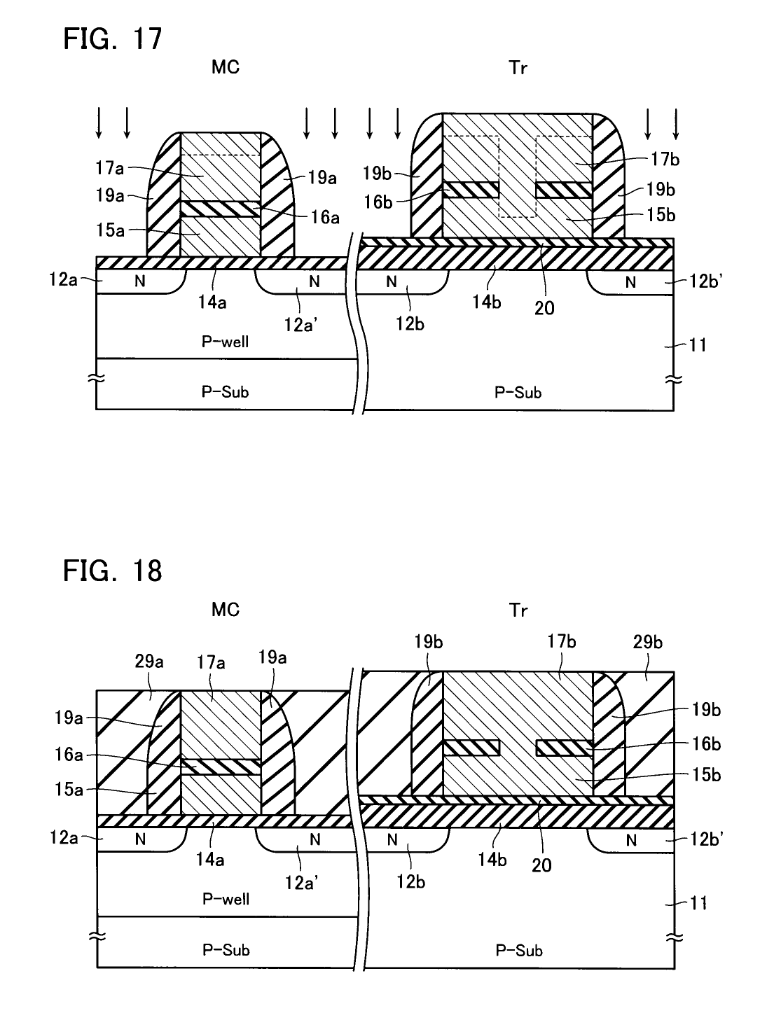

As shown in FIG. 17, an impurity such as phosphorus (P) is ion-implanted into the surface of the semiconductor substrate 11 at a concentration of, for example, 1×10¹⁸ cm⁻³ using the sidewalls 19a and 19b as masks. The n type impurity diffusion regions 12a, 12b, 12a′, and 12b′ are thus formed in self-alignment.

As shown in FIG. 18, an interlayer dielectric film such as a TEOS film is deposited over the entire surface by, for example, plasma CVD to be embedded between the gate electrodes 18a and 18b. The surface is then planarized by CMP and the like to form gate isolation layers 29a and 29b. During this process, the gate electrodes 17a and 17b function as stopper films. The gate isolation layer 29a electrically isolates the gate electrodes 18a of the memory cell transistor MC. The gate isolation layer 29b electrically isolates the gate electrode 18b of the high voltage operation peripheral transistor (HV-Tr) and other devices.

In conventional NAND flash memory, along with the gate-insulating film of the memory cell transistor, the gate-insulating film of the high voltage operation peripheral transistor is oxynitrided. It is known that the oxynitride film has a positive fixed electric charge. The positive fixed electric charge may shift the flat band voltage Vfd of the gate-insulating film of the high voltage operation peripheral transistor in the direction of lower voltages, thus reducing the threshold voltage of the high voltage operation peripheral transistor (HV-Tr). To address this issue, in conventional memories, the impurity concentration in the channel region is increased to compensate for the reduction of the flat band voltage Vfd. Specifically, for the n type channel transistor, an impurity such as boron (B) is ion-implanted into the channel region in advance. This reduces the depletion layer spread between the source and the channel, thus decreasing the junction breakdown voltage. A high voltage operation at about 30 V may therefore cause problems such as decreasing the surface breakdown and increasing the leak current.

In contrast, according to the present invention, the gate-insulating film of the memory cell transistor is oxynitrided, thereby allowing for reduction of the electron trap effect. In addition, the gate-insulating film 14b of the high voltage operation peripheral transistor is covered by the barrier film 20, thus reducing the oxynitridation of the underlying gate-insulating film 14b. The gate-insulating film 14b that isolates the barrier film 20 from the semiconductor substrate 11 is relatively thick. Even if, therefore, the silicon nitride film included in the barrier film 20 has a positive fixed electric charge, the affect of the charge may be small and the threshold voltage variation due to the flat band voltage Vfb shift may be negligible. There is thus no need to increase the impurity concentration in the channel region, thereby allowing for the depletion layer spread between the source and the channel and thus increasing a sufficient breakdown voltage.

The term “the oxynitridation is reduced” means that “the oxynitridation of the gate-insulating film 14b near the boundary between the semiconductor substrate 11 and the gate-insulating film 14b is reduced.” This is because the fixed electric charge near the semiconductor substrate 11 may shift the flat band voltage Vfb. In other words, oxynitridation of the gate-insulating film 14b near the boundary between the barrier film 20 and the gate-insulating film 14b will not affect the advantages of the invention.

In addition, the barrier film 20 will not affect the switching operation of the high voltage operation peripheral transistor (HV-Tr). This is because if the barrier film is an insulating film, for example, a laminate of the gate-insulating film and the barrier film may function as the gate-insulating film of the high voltage operation peripheral transistor (HV-Tr). If the barrier film is an electrical conductor, for example, it may function as a portion of the gate electrode, thereby not affecting the switching operation of the high voltage operation peripheral transistor (HV-Tr).

In the peripheral transistor region, no impurity may be ion-implanted into the channel region, thus reducing the impurity concentration in the channel region to the impurity concentration of the semiconductor substrate. Some of the manufacturing steps may thus be omitted. Because there is no need to increase the threshold voltage, even the well region may be omitted.

In this way, in the NAND flash memory according to this embodiment, it may be possible to control the electron trap effect due to the gate-insulating film of the memory cell transistor while ensuring a sufficient high breakdown voltage of the high voltage operation peripheral transistor. It may thus be possible to provide a highly reliable NAND flash memory.

### Second Embodiment

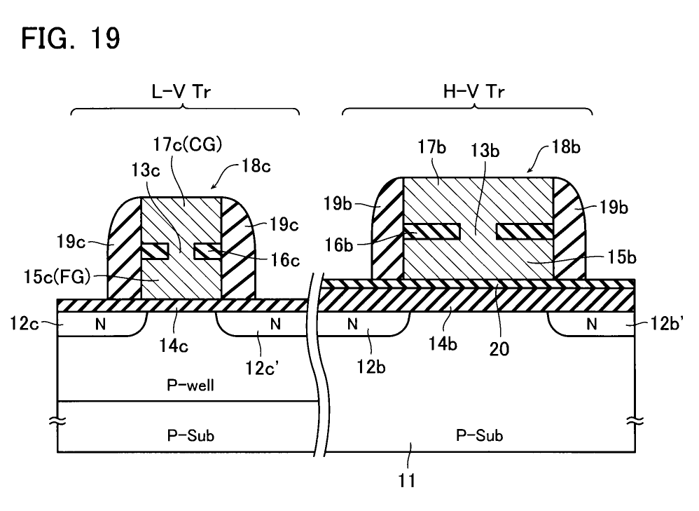

FIG. 19 is a schematic cross-sectional view of a low voltage operation peripheral transistor region and a high voltage operation peripheral transistor region of a semiconductor device according to a second embodiment of the present invention. Unlike the first embodiment, the memory cell transistor is replaced by the low voltage operation peripheral transistor. Note that in the second embodiment, like elements as those in the first embodiment are designated with like reference numerals and their description is omitted here.

The configuration of the low voltage operation peripheral transistor (LV-Tr) corresponding to a first transistor will be described. The low voltage operation peripheral transistor includes, for example, a transistor that operates at a voltage of about 1.0 to 5.0 V. The low voltage operation peripheral transistor (LV-Tr) includes the p type silicon substrate 11, an insulating film 14c formed on the p type silicon substrate 11, the film 14c including, for example, a silicon oxide film, and a gate electrode 18c formed on the insulating film 14c. The gate electrode 18c includes a lower gate 15c including, for example, electrically conductive polysilicon doped with impurities such as phosphorus (P), an inter-gate dielectric film 16c deposited on the lower gate 15c, and an upper gate 17c formed on the lower gate 15c via the inter-gate dielectric film 16c. The gate-insulating film 14c is oxynitrided. The film 14c includes, for example, an oxynitride film SiOₓN_{y} having a thickness of about 2 nm to 10 nm. The oxynitride film may decrease electron traps in the gate-insulating film 14c, thus reducing a leak current through the gate electrode 18c and the semiconductor substrate 11.

The gate-insulating film 14c has a higher nitrogen atom concentration than the gate-insulating film 14b. The inter-gate dielectric film 16c deposited on top of the lower gate 15c may have a high dielectric constant and include, for example, an ONO film (SiO₂/SiN/SiO₂) having a thickness of about 7 nm to about 20 nm deposition. The inter-gate dielectric film 16c has an opening 13c formed at its generally center portion on the top surface of the lower gate 15c. The upper gate 17c deposited on top of the inter-gate dielectric film 16c may include, for example, electrically conductive polysilicon.

The upper gate 17c is in electrical connection with the lower gate 15c via the opening 13c. This structure allows the gate electrode 18c of the low voltage operation peripheral transistor (LV-Tr) to have a one-layer structure.

The sides of the gate electrode 18c each have a sidewall 19c formed thereon. The sidewall 19c includes, for example, a silicon nitride film or a silicon oxide film. The surface of the p type silicon substrate 11 has n type impurity diffusion regions 12b and 12b′ formed thereon. The impurity diffusion regions 12b and 12b′ are formed in self-alignment with the gate electrode 18c and sandwich the electrode 18c. The regions 12b and 12b′ are doped with impurities for the source or drain such as phosphorus (P) and the like.

The p type silicon substrate 11 in the low voltage operation peripheral transistor region may a p type well that has a higher impurity concentration than the p type silicon substrate 11. The low voltage operation transistor (LV-Tr) may thus have a higher threshold. The cut-off characteristics may thus be improved even if the transistor has a shorter gate length when it is reduced in size. A channel region is formed in the surface of the semiconductor substrate 11 that is sandwiched between the n type impurity diffusion regions 12c and 12c+. The channel region may adjust the threshold voltage of the low voltage operation peripheral transistor (LV-Tr).

### Third Embodiment

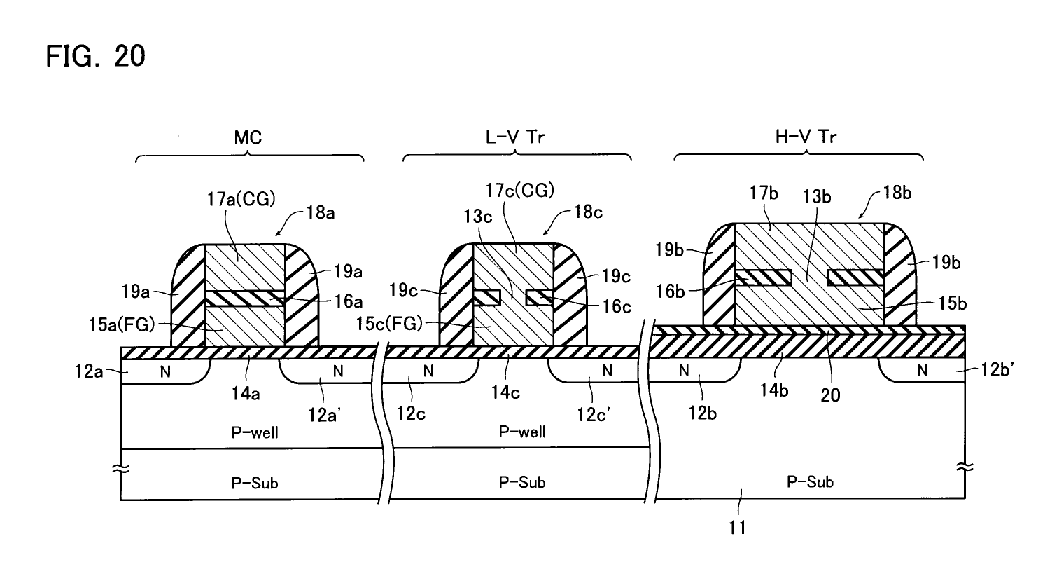

FIG. 20 is a schematic cross-sectional view of a non-volatile memory cell area, a low voltage operation peripheral transistor region, and a high voltage operation peripheral transistor region of a semiconductor device according to a third embodiment of the present invention. Unlike the first embodiment, the first transistor includes the memory cell transistor of the first embodiment as well as the low voltage operation peripheral transistor of the second embodiment. Note that in the third embodiment, like elements as those in the first and second embodiments are designated with like reference numerals and their description is omitted here.

With reference to FIG. 20, the semiconductor device includes the memory cell transistor (MC) as well as the low voltage operation transistor (LV-Tr). The gate-insulating film 14a of the memory cell transistor (MC) is similar to the gate-insulating film 14c of the low voltage operation transistor (LV-Tr). This structure may increase the breakdown voltage of the high voltage operation peripheral transistor. A non-volatile semiconductor memory may thus be provided that has improved reliability of the memory cell transistor and the low voltage operation peripheral transistor.

In the manufacturing steps, the gate-insulating film 14c of the low voltage operation peripheral transistor (LV-Tr) may be manufactured in a similar way to the gate-insulating film 14a of the memory cell transistor (MC) as shown in the steps in FIG. 2 to FIG. 8. In addition, the gate electrode 17c of the low voltage operation peripheral transistor (LV-Tr) may be manufactured in a similar way to the gate electrode 17b of the high voltage operation peripheral transistor (HV-Tr) as shown in the steps in FIG. 9 to FIG. 16. Specifically, with no more steps than those in the first embodiment, the structure of the third embodiment may be manufactured.

Thus, although the invention has been described with respect to particular embodiments thereof, it is not limited to those embodiments. It will be understood that various modifications and additions and the like may be made without departing from the spirit of the present invention. For example, the memory cell transistor may also be applied to the NAND flash memory and a NOR flash memory. Additionally, the memory cell transistor may also be applied to a logic circuit as in the second embodiment.

What is claimed is:

1. A semiconductor memory device comprising:
a first transistor formed on a semiconductor substrate, the first transistor including a first gate-insulating film that is oxynitrided; and
a second transistor comprising a second gate-insulating film formed on the semiconductor substrate and a barrier film formed at least partially on the second gate-insulating film,
the second gate-insulating film having a lower nitrogen atom concentration than the first gate-insulating film.

2. The semiconductor memory device according to claim 1, wherein
the second transistor comprises a gate electrode formed on the barrier film.

3. The semiconductor memory device according to claim 1, wherein
the second gate-insulating film is thicker than the first gate-insulating film.

4. The semiconductor memory device according to claim 1, wherein
the second transistor is a high voltage operation peripheral transistor, and
the first transistor is a memory cell transistor or a low voltage operation peripheral transistor.

5. The semiconductor memory device according to claim 1, wherein
the barrier film includes at least one of silicon nitride and silicon fluoride.

6. The semiconductor memory device according to claim 2 further comprising,
impurity diffusion regions are formed in the semiconductor substrate sandwiched the gate electrode, and
a channel region is formed in a surface of the semiconductor substrate;
a impurity concentration of channel region is same as that of the semiconductor substrate

7. The semiconductor memory device according to claim 1, wherein
the the second gate-insulating film includes an oxynitride film, and the first gate-insulating film includes a silicon oxide film.

8. A method of manufacturing a semiconductor memory device, comprising the steps of:
forming a first gate-insulating film on a semiconductor substrate in a region where a first transistor is to be formed, and forming a second gate-insulating film that is thicker than the first gate-insulating film on the semiconductor substrate in a region where a second transistor is to be formed;
forming a barrier film on the second gate-insulating film; and
oxynitriding the first gate-insulating film using the barrier film as a mask.

9. The method of manufacturing a semiconductor memory device according to claim 8, further comprising the step of forming a gate electrode on the barrier film and the first gate-insulating film.

10. The method of manufacturing a semiconductor memory device according to claim 8, wherein
the second transistor is a high voltage operation peripheral transistor, and
the first transistor is a memory cell transistor or a low voltage operation peripheral transistor.

11. The method of manufacturing a semiconductor memory device according to claim 8, wherein
the oxynitriding is annealed the first gate-insulating film in an atmosphere of an ammonia gas or an oxidation nitrogen gas C.

12. The method of manufacturing a semiconductor memory device according to claim 8, wherein
the barrier film includes at least one of silicon nitride and silicon fluoride.

13. A method of manufacturing a semiconductor memory device, comprising the steps of:
forming an insulating film on a semiconductor substrate;
forming a barrier film on the insulating film;
removing the insulating film and the barrier film in a first region where a first transistor is to be formed, thus exposing the semiconductor substrate;
forming a first gate-insulating film in the first region where the insulating film and barrier film are removed; and
oxynitriding the first gate-insulating film using the barrier film as a mask.

14. The method of manufacturing a semiconductor memory device according to claim 13, wherein
the second insulating film, which is an insulating film other than the first gate-insulating film, is thicker than the first gate-insulating film.

15. The method of manufacturing a semiconductor memory device according to claim 13, further comprising the step of forming a gate electrode on the barrier film and the first gate-insulating film, and
the second transistor is formed in a region where the barrier film remains.

16. The semiconductor memory device according to claim 15, wherein
the second transistor is a high voltage operation peripheral transistor, and
the first transistor is a memory cell transistor or a low voltage operation peripheral transistor.

17. The method of manufacturing a semiconductor memory device according to claim 13, wherein
the oxynitriding is annealed the first gate-insulating film in an atmosphere of an ammonia gas or an oxidation nitrogen gas.

18. The method of manufacturing a semiconductor memory device according to claim 13, wherein
the barrier film includes at least one of silicon nitride and silicon fluoride.
